(19) United States
(12) Patent Application Publication
(10) Pub. No.: US 2025/0169270 A1
(43) Pub. Date: May 22, 2025

(54) LIGHT EMITTING DISPLAY DEVICE

(71) Applicant: Samsung Display Co., LTD., Yongin-si (KR)

(72) Inventors: Dae Ho LEE, Yongin-si (KR); Hyo Joon KIM, Yongin-si (KR)

(73) Assignee: Samsung Display Co., LTD., Yongin-si (KR)

(21) Appl. No.: 18/791,923

(22) Filed: Aug. 1, 2024

(30) Foreign Application Priority Data
Nov. 16, 2023 (KR) 10-2023-0159081

(51) Int. Cl. H10K 39/34; G06V 40/13; H10K 59/122; H10K 59/38; H10K 59/80

(52) U.S. Cl. CPC H10K 39/34; H10K 59/122; H10K 59/38; H10K 59/8792; G06V 40/1318

(57) ABSTRACT

A light emitting display device includes a pixel circuit and light sensing circuit unit on a substrate, light emitting elements connected to the pixel circuit unit and including a first and second electrode and a light emitting layer, a light receiving element connected to the light sensing circuit unit and including a first and second electrode and a sensing layer, a first color conversion layer on the light emitting elements, a transparent layer on the light emitting and receiving elements, and a color filter on the first color conversion layer and first transparent layer. The first electrode of the light emitting elements and the light receiving element are located on a same layer, the second electrode of the light emitting elements and light receiving element are located on a same layer and electrically connected, and the light emitting layers and the sensing layer are located on a same layer.

### CROSS-REFERENCE TO RELATED APPLICATION(S)

This application claims priority to and the benefits of Korean Patent Application No. 10-2023-0159081 under 35 U.S.C. § 119, filed on Nov. 16, 2023, in the Korean Intellectual Property Office (KIPO), the entire contents of which are incorporated herein by reference.

### BACKGROUND

### 1. Technical Field

The disclosure relates to a light emitting display device including an optical sensor unit in a display area.

### 2. Description of the Related Art

A display device is a device that displays a screen and includes a liquid crystal display (LCD) and an organic light emitting diode (OLED).

These display devices are used in various electronic devices such as mobile phones, navigation devices, digital cameras, electronic books, portable game consoles, and various terminals.

A display device, such as an organic light emitting display device, may have a structure that can be bent or folded using a flexible substrate.

The structure of pixels used in such organic light emitting display devices is being developed in various directions.

Additionally, display devices including light emitting display devices are being developed to include sensors in the display area to enable sensing as well as display of images.

### SUMMARY

Embodiments are intended to provide a light emitting display device in which a sensing unit including a light receiving element is formed next to the display unit in the display area.

A light emitting display device according to an embodiment may include a first pixel circuit unit, a second pixel circuit unit, and a light sensing circuit unit located on a substrate, a first light emitting element electrically connected to the first pixel circuit unit, a second light emitting element electrically connected to the second pixel circuit unit, a light receiving element electrically connected to the light sensing circuit unit, a first color conversion layer located on the first light emitting element, a first transparent layer for pixels located on the second light emitting element, a first transparent layer for detection located on the light receiving element, a first color filter located on the first color conversion layer; and a second color filter located on the first transparent layer for pixels. The first light emitting element may include a first electrode, a first light emitting layer, and a second electrode, the second light emitting element may include the first light emitting element comprising an electrode, a second light emitting layer, and a second electrode, and the light receiving element may include a first electrode, a sensing layer, and a second electrode. The first electrode of the first light emitting element, the first electrode of the second light emitting element, and the first electrode of the light receiving element may be located on a same layer as, the second electrode of the first light emitting element, the second electrode of the second light emitting element, and the second electrode of the light receiving element may be located on a same layer and electrically connected, and the first light emitting layer, the second light emitting layer, and the sensing layer may be located on a same layer.

The first light emitting layer and the second light emitting layer may emit blue light.

The first color filter may be a red color filter or a green color filter, and the second color filter may be a blue color filter.

The light emitting display device may further include a second transparent layer located on the first transparent layer for sensing.

The first light emitting element may further include a functional layer located between the first light emitting layer and the first electrode or between the first light emitting layer and the second electrode, and the light receiving element may further include a functional layer. The functional layer of the light receiving element and the functional layer of the first light emitting element may be formed continuously.

The functional layer of the first light emitting element and the functional layer of the light receiving element may be at least one of a hole injection layer, a hole transport layer, an electron injection layer, and an electron transport layer.

The hole injection layer and the hole transfer layer may be located between the first light emitting layer and the first electrode, and the electron injection layer and the electron transfer layer may be located between the first light emitting layer and the second electrode.

The light emitting display device may further include an additional light emitting layer, and a charge generation layer between the first light emitting layer and the additional light emitting layer.

The charge generation layer may be positioned between the hole transport layer and the electron transport layer.

The light emitting display device may further include a pixel defining layer partitioning the first light emitting element, the second light emitting element, and the light receiving element, and a wall partitioning the first color conversion layer, the first transparent layer for pixels, and the first transparent layer for sensing.

The wall may have reverse tapered sides.

The wall may include a light-absorbing material.

The light emitting display device may further include a low refractive index layer covering the wall, the first color conversion layer, the first transparent layer for pixels, and the first transparent layer for sensing.

The light emitting display device may further include a lower insulating layer for a low refractive index layer positioned between the low refractive index layer and the wall, the first color conversion layer, the first transparent layer for pixels, and the first transparent layer for sensing, and an upper insulating layer for the low refractive index layer positioned between the low refractive index layer and the first color filter and the second color filter.

The lower insulating layer for the low refractive index layer may have a step.
an overlapping portion where the first color filter and the second color filter overlap in a plan view may overlap the wall in a plan view.

A light emitting display device according to an embodiment may include a first pixel circuit and a light sensing circuit located on a substrate, a first light emitting element electrically connected to the first pixel circuit, a light receiving element electrically connected to the light sensing circuit, a first color conversion layer located on the first light emitting element, a first transparent layer for sensing located on the light receiving element, a first color filter located on the first color conversion layer, and a second transparent layer located on the first transparent layer for sensing. The first light emitting element may include a first electrode, a first light emitting layer, a second electrode, and a functional layer located between the first light emitting layer and the first electrode or between the first light emitting layer and the second electrode. The light receiving element may include a first electrode, a detection layer, a second electrode, and a functional layer, and the functional layer of the light receiving element and the functional layer of the first light emitting element may be continuously formed.

The light emitting display device may further include a pixel defining layer dividing the first light emitting element and the light receiving element, and a wall dividing the first color conversion layer and the first transparent layer for sensing.

The light emitting display device may further include a second pixel circuit unit located on the substrate, a second light emitting element electrically connected to the second pixel circuit unit, a first transparent layer for pixels located on the second light emitting element, and a second color filter located on the first transparent layer for pixels. The second light emitting element may include a first electrode, a second light emitting layer, a second electrode, and a functional layer located between the second light emitting layer and the first electrode or between the second light emitting layer and the second electrode. The functional layer of the light receiving element and the functional layer of the second light emitting element may be formed continuously.

The light emitting display device may further include a low refractive index layer covering the wall, the first color conversion layer, the first transparent layer for pixels, and the first transparent layer for sensing.

According to embodiments, a sensing unit may be formed next to the display unit in the display area of the light emitting display device to enable a sensing operation in addition to displaying an image.

In addition, according to the light emitting display device of an embodiment, a light emitting layer and a light receiving layer may be located between the cathode and anode, a color conversion layer and a color filter may be located on the light emitting layer, and a transparent layer may be located on the light receiving layer, enabling sensing operation along with displaying an image without greatly changing the structure.

### BRIEF DESCRIPTION OF THE DRAWINGS

FIG. 1 is a schematic perspective view illustrating a use state of a light emitting display device according to an embodiment.

FIG. 2 is an exploded perspective view of a light emitting display device according to an embodiment.

FIG. 3 is an enlarged view of a portion of a display panel according to an embodiment.

FIG. 4 is a schematic cross-sectional view of a display panel according to an embodiment.

FIG. 5 is a schematic cross-sectional view of the display area of a display panel according to another embodiment.

FIG. 6 is a schematic cross-sectional view of a light emitting element and a light receiving element in a light emitting display device according to an embodiment.

FIG. 7 is a schematic cross-sectional view of a light emitting element in a light emitting display device according to another embodiment.

FIG. 8 is a schematic diagram of an equivalent circuit of one sensing unit included in a light emitting display device according to an embodiment.

FIG. 9 is a waveform diagram showing the signal applied to the sensing unit of FIG. 8.

### DETAILED DESCRIPTION OF THE EMBODIMENTS

Hereinafter, with reference to the attached drawings, various embodiments will be described in detail so that those skilled in the art can readily implement the disclosure.

The disclosure may be implemented in many different forms and is not limited to the embodiments described herein.

In order to clearly explain the disclosure, parts that are not relevant to the description are omitted, and identical or similar components are assigned the same reference numerals throughout the specification.

In addition, the size and thickness of each component shown in the drawings are arbitrarily shown for convenience of explanation, so the disclosure is not necessarily limited to that which is shown.

In the drawings, the thickness is enlarged to clearly express various layers and areas.

And in the drawings, for convenience of explanation, the thicknesses of some layers and regions are exaggerated.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In addition, throughout the specification, when reference is made to “on a plane” or “in a plan view”, this means when the target portion is viewed from above, and when reference is made to “in cross-section” or “in a cross-sectional view”, this means when a cross-section of the target portion is cut vertically and viewed from the side.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In addition, throughout the specification, when a portion such as a wiring, layer, film, region, plate, or component is said to “extend in the first or second direction,” this does not mean only a straight shape extending in that direction, but also a structure that extends overall along the first or second direction, and also includes a structure that is bent at some part, has a zigzag structure, or extends while including a curved structure.

In addition, electronic devices (e.g., mobile phones, TVs, monitors, laptop computers) containing display devices, display panels, etc. described in the specification, or display devices, display panels, etc. manufactured by the manufacturing method described in the specification are not excluded from the scope of rights of this specification.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

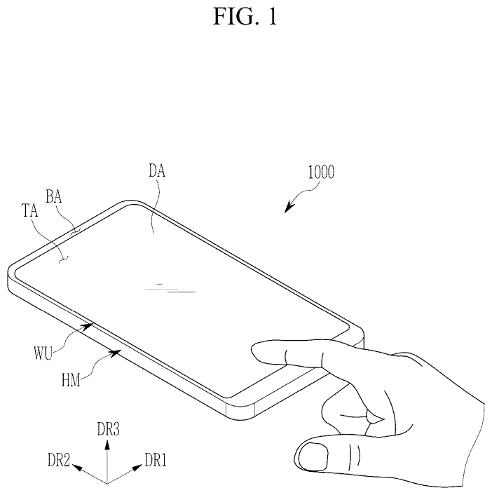

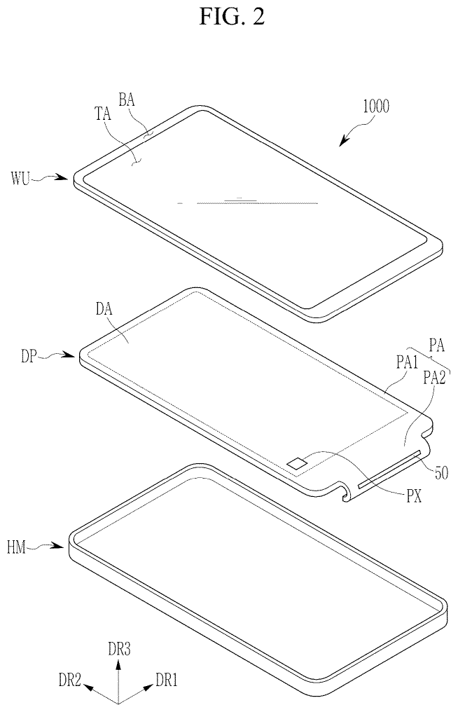

Below, the structure of the light emitting display device through FIGS. 1 and 2 will be described.

FIG. 1 is a schematic perspective view showing a use state of a light emitting display device according to an embodiment, and FIG. 2 is an exploded perspective view of a light emitting display device according to an embodiment.

Referring to FIG. 1, the light emitting display device 1000 according to an embodiment may be a device that displays moving or still images, and may be used as a display screen for various products such as mobile phones, smartphones, tablet PCs, mobile communication terminals, electronic notebooks, e-books, portable multimedia players (PMP), navigation, ultra mobile PCs (UMPC), as well as televisions, laptops, monitors, billboards, and the Internet of Things (IOT).

A light emitting display device 1000 according to an embodiment may be used in wearable devices such as a smart watch, watch phone, glasses-type display, and head-mounted display HMD.

The light emitting display device 1000 according to one embodiment may include a dashboard of a car, a center information display CID placed on the center fascia or dashboard of a car, and a room mirror display (a room mirror display instead of a side mirror of a car), room mirror display), or may be used as entertainment for the back seat of a car, and as a display placed on the back of the front seat.

FIG. 1 shows the light emitting display device 1000 being used as a smart phone, for convenience of explanation.

The light emitting display device 1000 may display an image in the third direction DR3 on a display surface parallel to each of the first and second directions DR1 and DR2.

The display surface on which the image is displayed may correspond to the front surface of the light emitting display device 1000 and the front surface of the cover window WU.

Images may include static images as well as dynamic images.

In this embodiment, the front (or top) and back (or bottom) surfaces of each member are defined based on the direction in which the image is displayed.

The front and back surfaces are opposed to each other in the third direction DR3, and the normal directions of each of the front and back surfaces may be parallel to the third direction DR3.

The separation distance between the front and back surfaces in the third direction DR3 may correspond to the thickness of the display panel in the third direction DR3.

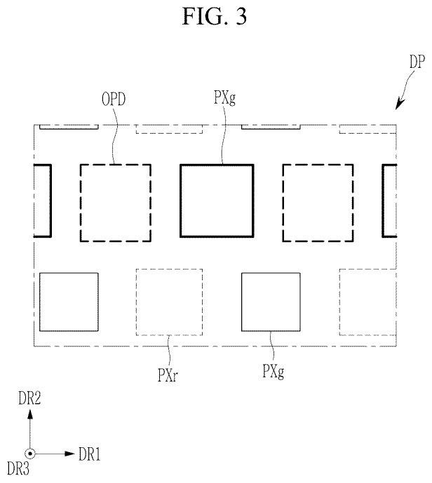

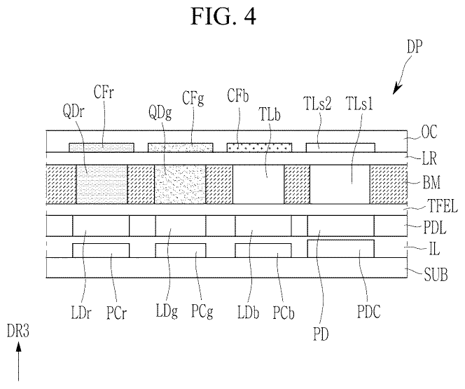

According to one embodiment, the light emitting display device 1000 may include a sensing unit (refer to FIGS. 3 and 4) that contains a light receiving element such as a photodiode in the display area DA, and may detect a user's input (refer to the hand in FIG. 1) that is applied from the outside.

The user's input may include various types of external inputs, such as parts of the user's body, light, heat, or pressure.

In one embodiment, the user's input may be provided with the user's hand to the front. However, the disclosure is not limited to this.

The user's input may be provided in various forms, and the light emitting display device 1000 may detect the user's input applied to the side or back of the light emitting display device 1000 depending on the structure of the light emitting display device 1000.

Referring to FIGS. 1 and 2, the light emitting display device 1000 may include a cover window WU, a housing HM, and a display panel DP.

In one embodiment, the cover window WU and the housing HM may be combined to configure the exterior of the light emitting display device 1000.

The cover window WU may include an insulating panel.

For example, the cover window WU may be made of glass, plastic, or a combination thereof.

The front of the cover window WU may define the front of the light emitting display device 1000.

The transmission area TA may be an optically transparent area.

For example, the transmission area TA may be an area with a visible light transmittance of greater than or equal to about 90%.

The blocking area BA may define the shape of the transmission area TA in a plan view.

The blocking area BA may be adjacent to the transmission area TA and may surround the transmission area TA in a plan view.

The blocking area BA may be an area with relatively low light transmittance compared to the transmission area TA.

The blocking area BA may include an opaque material that blocks light.

The blocking area BA may have a color.

The blocking area BA may be defined by a bezel layer provided separately from the transparent substrate defining the transmission area TA, or may be defined by an ink layer formed by inserting or coloring the transparent substrate.

The display panel DP may include a display panel DP that displays an image and a driver 50.

The display panel DP may include a front surface including a display area DA and a non-display area PA.

The display area DA may be an area where pixels operate according to electrical signals to emit light, and may include a sensing unit including a light receiving element to detect external input.

The transmission area TA of the cover window WU may at least partially overlap the display area DA of the display panel DP in a plan view.

For example, the transmission area TA may overlap the entire surface of the display area DA or may overlap at least a portion of the display area DA in a plan view.

Accordingly, the user may view the image through the transmission area TA or provide external input based on the image.

However, the disclosure is not limited to this.

For example, in the display area DA, an area where an image is displayed and an area where an external input is detected may be separated from each other.

The non-display area PA of the display panel DP may at least partially overlap the blocking area BA of the cover window WU in a plan view.

The non-display area PA may be an area covered by the blocking area BA.

The non-display area PA may be adjacent to the display area DA and may surround the display area DA in a plan view.

An image may not be displayed in the non-display area PA, and a driving circuit or driving wiring for driving the display area DA may be disposed in the non-display area PA.

The non-display area PA may include a first peripheral area PA1 located outside the display area DA and a second peripheral area PA2 including the driver 50, connection wiring, and a bending area.

In the embodiment of FIG. 2, the first peripheral area PA1 is located on the third side of the display area DA, and the second peripheral area PA2 is located on the remaining side of the display area DA.

In one embodiment, the display panel DP may be assembled in a flat state with the display area DA and the non-display area PA facing the cover window WU.

However, the disclosure is not limited to this.

A portion of the non-display area PA of the display panel DP may be curved.

A part of the non-display area PA may be directed toward the rear of the light emitting display device 1000, so that the blocking area BA visible on the front of the light emitting display device 1000 may be reduced, and in FIG. 2, the second peripheral area PA2 may be bent and placed on the back of the display area DA and assembled.

The display area DA may be divided into a display unit and a sensing unit, where the display unit may include pixels (see PXr, PXg, and PXb in FIG. 3) including light emitting elements such as light emitting diodes that display images, and the sensing unit (see FIG. 3) (see OPD in FIG. 3) may include a light receiving element such as a photo diode.

The display unit may be formed with multiple light emitting elements and multiple pixel circuit unit (hereinafter also referred to as first circuit units) that generate and transmit light emitting current to each of the light emitting elements.

One light emitting element and one pixel circuit unit may be referred to as a pixel.

In the display unit, one pixel circuit unit and one light emitting element may be connected one-to-one, and according to an embodiment, multiple light emitting elements may be connected to one pixel circuit unit.

The sensing unit may include multiple light receiving elements, and a light sensing circuit unit (hereinafter also referred to as a second circuit unit) that is connected to each of the light receiving elements to perform a sensing operation.

In the sensing unit, one light receiving element and one light sensing circuit unit may be connected in a one-to-one connection.

The second peripheral area PA2 may include a bending portion.

The display area DA and the first peripheral area PA1 may have a flat state substantially parallel to the plane defined by the first direction DR1 and the second direction DR2, and a side of the second peripheral area PA2 may be extended from a flat state, pass through a bending portion, and be in a flat state again.

As a result, at least a portion of the second peripheral area PA2 may be bent and assembled to be located on the rear side of the display area DA.

In case that at least a portion of the second peripheral area PA2 is assembled, the portion of the second peripheral area PA2 may overlap the display area DA in a plan view, so the blocking area BA of the light emitting display device 1000 may be reduced.

However, the disclosure is not limited to this.

For example, the second peripheral area PA2 may not be bent.

The driver 50 may be mounted on the second peripheral area PA2, on the bending part, or located on one of sides of the bending part.

The driver 50 may be provided in the form of a chip.

The driver 50 may be electrically connected to the display area DA and may transmit an electrical signal to the display area DA.

For example, the driver 50 may provide data signals to the pixels PX arranged in the display area DA.

For example, the driver 50 may include a touch driving circuit and may be electrically connected to a sensing unit including a light receiving element disposed in the display area DA.

The driver 50 may include various circuits in addition to the above-described circuits or may be designed to provide various electrical signals to the display area DA.

The light emitting display device 1000 may have a pad portion located at an end of the second peripheral area PA2, and may be electrically connected to a flexible printed circuit board (FPCB) including a driving chip by the pad portion.

The driving chip located on the flexible printed circuit board may include various driving circuits for driving the light emitting display device 1000 or a connector for power supply.

According to an embodiment, a rigid printed circuit board PCB may be used instead of a flexible printed circuit board.

The housing HM may be combined with the cover window WU.

The cover window WU may be disposed on the front of the housing HM.

The housing HM may be combined with the cover window WU to provide an accommodation space.

The display panel DP may be accommodated in an accommodation space provided between the housing HM and the cover window WU.

The housing HM may include a material with relatively high rigidity.

For example, the housing HM may include multiple frames and/or plates made of glass, plastic, a metal, or a combination thereof.

The housing HM may stably protect the components of the light emitting display device 1000 accommodated in the internal space from external shock.

In the above, the light emitting display device was schematically described as a whole through FIGS. 1 and 2.

Hereinafter, the display panel DP included in the light emitting display device will be described in detail through FIGS. 3 and 4.

First, the planar structure of FIG. 3 will be described.

FIG. 3 is an enlarged view of a portion of a display panel according to an embodiment.

In FIG. 3, a part of the display area of the display panel DP is enlarged and shown, and in one embodiment, the pixels PXr, PXg, PXb included in the display area and the position on the plane of the sensing unit OPD are shown as a rectangle.

Multiple pixels PXr, PXg, PXb may each correspond to one of the three primary colors of light—for example, red, green, and blue, and correspond to the display unit.

In FIG. 3, each pixel PXr, PXg, PXb may be distinguished through different outlines, and the rectangles in FIG. 3 may be used to roughly indicate the position, and the shape of the pixels PXr, PXg, PXb is not limited to the rectangular plane shape.

According to an embodiment, each pixel PXr, PXg, PXb may have various planar shapes, such as a circle, or may have a polygonal structure with chamfered edges in a plan view.

Each pixel PXr, PXg, PXb may be electrically connected to a light emitting element and include a pixel circuit unit that generates and transmits a light emitting current to the light emitting element.

Each pixel PXr, PXg, PXb illustrated in FIG. 3 is a view from the top of the display panel DP, so the pixel PXr, PXg, PXb may correspond to the light emitting element, and the pixel circuit unit may be located below the light emitting element.

The sensing unit OPD may be located between the pixels PXr, PXg, PXb.

According to the embodiment of FIG. 3, multiple pixels PXr, PXg, PXb may be arranged in two rows, with only the green pixel PXg arranged in the first row, and the red pixel PXr and the blue pixel PXb arranged alternately in the second row.

In this arrangement of the display unit, the light receiving element PD may be arranged between the green pixels PXg in the first row, and the green pixels PXg and the sensing unit OPD may be arranged alternately in the first row.

The arrangement of the pixels PXr, PXg, PXb is not limited to the embodiment in FIG. 3, a different arrangement is possible, and according to another embodiment, at least one of the pixels PXr, PXg, PXb may be formed in twice the number of other pixels.

The sensing unit OPD may be electrically connected to the light receiving element, and include a light sensing circuit unit that can detect a voltage changed due to a touch in the light receiving element.

Since the sensing unit OPD shown in FIG. 3 is viewed from the top of the display panel DP, the sensing unit OPD may correspond to a light receiving element among the sensing units OPD, and the light sensing circuit unit may be located below the light receiving element.

The sensing unit OPD shown as a square in FIG. 3 may roughly indicate its position, and the sensing unit OPD, especially the light receiving element, does not need to have a rectangular planar shape in a plan view.

The sensing unit OPD or the light receiving element may have various planar shapes, such as a circle, or may have a polygonal structure with chamfered edges.

In the above, the planar arrangement of each pixel PXr, PXg, PXb and sensing unit OPD corresponding to an embodiment of the display unit was described through FIG. 3.

Hereinafter, a cross-sectional structure of the display panel DP will be described through FIG. 4.

FIG. 4 is a schematic cross-sectional view of a display panel according to an embodiment.

The display panel DP may include a substrate SUB, insulating layer IL, pixel defining layer PDL, encapsulation layer TFEL, wall BM, low refractive index layer LR, and planarization layer OC sequentially stacked.

The pixel circuit unit PCr, PCg, PCb of the pixel and the light sensing circuit unit PDC of the sensing unit may be located on the substrate SUB, and the pixel circuit unit PCr, PCg, PCb and the light sensing circuit unit PDC may be covered with an insulating layer IL.

The light emitting elements LDr, LDg, LDb of the pixel and the light receiving element PD of the sensing unit may be located above the insulating layer IL and between the pixel defining layer PDL.

The color conversion layer QDr, QDg and the first transparent layer for sensing TLb, TLs1 may be located above the encapsulation layer TFEL and between the walls BM.

The color filters CFr, CFg, CFb and the second transparent layer TLs2 may be located above the low refractive index layer LR, and the color filters CFr, CFg, CFb and the second transparent layer TLs2 may be covered by the planarization layer OC.

Here, each light emitting element LDr, LDg, LDb may emit blue light.

For example, the blue light emitted from the light emitting element LDr may be changed to red light as it passes through the red color conversion layer QDr to form a red pixel, and additionally passes through the red color filter CFr to provide a clearer red light to the user's eyes.

The blue light emitted from the light emitting element LDg may be changed to green light as it passes through the green color conversion layer QDg to form a green pixel, and as it passes through the green color filter CFg, a clearer green light may be provided to the user's eyes.

Since the light emitting element LDb already emits blue light, the blue pixel may be constructed by passing through the first transparent layer for pixels TLb without including a separate color conversion layer and blue color filter CFb, a clearer blue light may be provided to the user's eyes.

The sensor part may be positioned to replace the color filter and color conversion layer with the first transparent layer for sensing TLs1 and the second transparent layer TLs2 to ensure that light can be transmitted without loss through the light receiving element PD without passing through the color filter or color conversion layer.

A closer look at the cross-sectional structure of FIG. 4 is as follows.

The substrate SUB may be a base substrate or a base member.

The substrate SUB may be a flexible substrate capable of bending, folding, rolling, etc.

For example, the substrate SUB may include a polymer resin including polyimide PI, but the disclosure is not limited thereto.

For example, the substrate SUB may include a glass material or a metal material.

The pixel circuit unit PCr, PCg, PCb and a light sensing circuit unit PDC may be disposed on the substrate SUB, and each of the pixel circuit unit PCr, PCg, PCb and the light sensing circuit unit PDC may include at least one transistor, and may be composed of multiple insulating layers, semiconductor layers, and multiple conductive layers.

The number and stacking structure of transistors included in the pixel circuit unit PCr, PCg, PCb and the light sensing circuit unit PDC may vary.

The pixel circuit unit PCr, PCg, PCb according to one embodiment may include one driving transistor and at least one switching transistor.

The driving transistor may generate an output current to be transmitted to the light emitting element, and a transistor of the at least one switching transistor may be connected to a data line to transmit the data voltage to the gate electrode of the driving transistor, and may further include various other transistors.

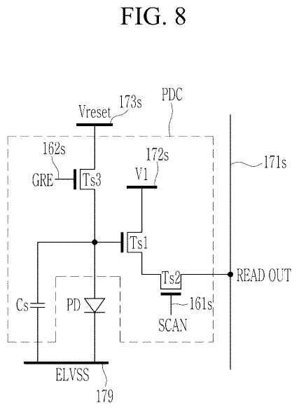

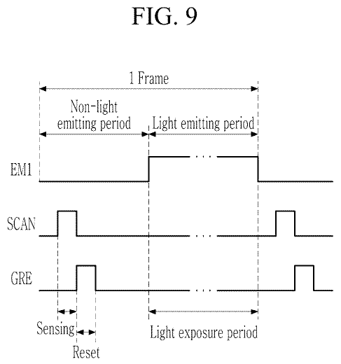

The light sensing circuit unit PDC according to one embodiment may have a circuit configuration as shown in FIG. 8 and may operate by signals as shown in FIG. 9.

The pixel circuit PCr, PCg, PCb and light sensing circuit unit PDC may be covered with an insulating layer IL.

According to an embodiment, the insulating layer IL may include multiple insulating layers, which may be disposed between and insulate semiconductor layers and/or conductive layers included in the pixel circuit PCr, PCg, PCb and the light sensing circuit unit PDC.

The insulating layer IL may include an organic insulating layer and/or an inorganic insulating layer.

Here, the semiconductor layer and the conductive layer included in the pixel circuit PCr, PCg, PCb and the light sensing circuit unit PDC may be positioned on a same layered insulating layer and may be formed through the same process.

A pixel defining layer PDL, light emitting elements LDr, LDg, LDb, and light receiving elements PD may be located on the insulating layer IL.

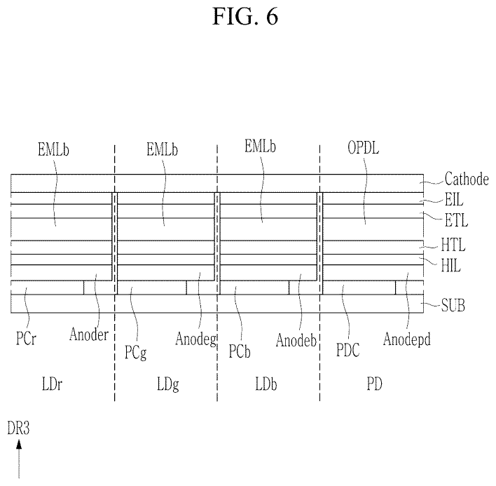

The pixel defining layer PDL may include multiple openings, and in each opening, a light emitting layer (EMLb in FIG. 6) and a sensing layer (OPDL in FIG. 6) included in the light emitting element LDr, LDg, LDb and the light receiving element PD may be located.

The first electrode (also called anode) and the second electrode (also called cathode) included in the light emitting elements LDr, LDg, LDb and light receiving elements PD may be located below and above the pixel defining layer PDL, and the pixel defining layer PDL may separate and insulate the first electrode and the second electrode.

The pixel defining layer PDL may be formed of a transparent organic material or a black organic material that includes a light-absorbing material to prevent reflection of external light.

The black organic material may include, for example, a polyimide (PI)-based binder and a mixture of red, green, and blue pigments, or a mixture of a cardo-based binder resin and lactam black pigment and blue pigment, or carbon black.

The light emitting elements LDr, LDg, LDb may each include a first electrode, a light emitting layer, and a second electrode, and may additionally include a functional layer located on sides of the light emitting layer, and including at least one of a hole injection layer, a hole transport layer, an electron injection layer, and an electron transport layer.

The light receiving element PD may include a first electrode, a sensing layer, and a second electrode. Functional layers included in the light emitting elements LDr, LDg, LDb may be located on sides of the sensing layer.

An encapsulation layer TFEL may be located on the pixel defining layer PDL, the light emitting elements LDr, LDg, LDb, and the light receiving element PD.

The encapsulation layer TFEL may include at least one inorganic layer and may prevent oxygen or moisture from penetrating into the light emitting layer.

The encapsulation layer TFEL may include at least one organic layer to protect the light emitting layer from foreign substances such as dust.

The encapsulation layer TFEL according to one embodiment may include a first encapsulation layer TFE1, a second encapsulation layer TFE2, and a third encapsulation layer TFE3.

The first encapsulation layer TFE1 and the third encapsulation layer TFE3 may be inorganic encapsulation layers, and the second encapsulation layer TFE2 disposed between them may be an organic encapsulation layer.

A wall BM, a color conversion layer QDr, QDg, and a first transparent layer TLb, TLs1 may be located on the encapsulation layer TFEL.

The wall BM may include multiple openings, and a color conversion layer QDr, QDg or a first transparent layer TLb, TLs1 may be located in each opening.

The opening of the wall BM may correspond to the opening of the pixel defining layer PDL and may be formed to be larger than the opening of the pixel defining layer PDL.

As the opening of the wall BM is formed larger than the opening of the pixel defining layer PDL, the light emitted from the light emitting elements LDr, LDg, LDb may be visible to the user not only from the front but also from the side of the light emitting display device 1000.

The wall BM may include a light-absorbing material to prevent light emitted from the light emitting elements LDr, LDg, LDb from invading and mixing colors, thereby improving the color gamut of the light emitting display device 1000.

The wall BM may include an inorganic black pigment or an organic black pigment.

The inorganic black pigment may be Carbon Black, and the organic black pigment may include at least one of Lactam Black, Perylene Black, and Aniline Black, but the disclosure is not limited to these.

The wall BM may be formed of the black organic material for the pixel defining layer PDL described above, and the pixel defining layer PDL may include an inorganic black pigment or an organic black pigment like the wall BM.

The wall BM may have a single-layer structure or a multi-layer structure.

For example, the wall BM may be designed to have a certain thickness or more in order to serve as a barrier capable of accommodating the ink composition, and for this purpose, the wall BM having a multi-layer structure may be formed.

The color conversion layer QDr, QDg may serve to convert the wavelength of light emitted from the light emitting element LDr, LDg into red light and green light, respectively. The light emitted from the light emitting elements LDr, LDg may have blue light.

For example, the color conversion layers QDr, QDg may include different semiconductor nanocrystals.

For example, light emitted from the light emitting layer incident on the red color conversion layer QDr may be converted into red light and emitted by the semiconductor nanocrystals included in the red color conversion layer QDr.

Light emitted from the light emitting layer incident on the green color conversion layer QDg may be converted into green light and emitted by the semiconductor nanocrystals included in the green color conversion layer QDg.

The semiconductor nanocrystal may include at least one of a phosphor and a quantum dot material that converts the light emitted from the incident light emitting layer into red or green.

As used herein, a quantum dot may be a crystal of a semiconductor compound, and may include a material that can emit light of various light emitting wavelengths according to the size of the crystal or by adjusting the element ratio in the quantum dot compound.

The diameter of the quantum dots may be, for example, in a range of about 1 nm to 10 nm.

Quantum dots may be synthesized by a wet chemical process, an organometallic chemical vapor deposition process, a molecular beam epitaxy process, or similar processes. The wet chemical process may be a method of growing quantum dot particle crystals after mixing organic solvents and precursor materials.

In case that a crystal grows, the organic solvent may naturally act as a dispersant coordinated to the surface of the quantum dot crystal and control the growth of the crystal, so metal organic chemical vapor deposition MOCVD or molecular beam epitaxy MBE may be used, and the growth of quantum dot particles may be controlled through an easier and lower-cost process than vapor deposition methods such as epitaxy.

Quantum dots may include group III-VI semiconductor compounds; Group II-VI semiconductor compounds; Group III-V semiconductor compounds; Group III-VI semiconductor compounds; Group I-III-VI semiconductor compounds; Group IV-VI semiconductor compounds; Group IV elements or compounds; or a combination thereof.

Examples of group II-VI semiconductor compounds may include binary compounds such as CdS, CdSe, CdTe, ZnS, ZnSe, ZnTe, ZnO, HgS, HgSe, HgTe, MgSe, MgS, etc.; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, etc.; quaternary compounds such as CdZnSeS, CdZnSeTe, CdZnSTe, CdHgSeS, CdHgSeTe, CdHgSTe, HgZnSeS, HgZnSeTe, HgZnSTe, etc.; or a combination thereof.

Examples of group III-V semiconductor compounds may include binary compounds such as GaN, GaP, GaAs, GaSb, AlN, AIP, AlAs, AlSb, InN, InP, InAs, InSb, etc.; ternary compounds such as GaNP, GaNAs, GaNSb, GaPAs, GaPSb, AlNP, AlNAs, AlNSb, AIPAS, AlPSb, InGaP, InNP, InAlP, InNAs, InNSb, InPAs, InPSb, GaAlNP, etc.; quaternary compounds such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, etc.; or a combination thereof.

The group III-V semiconductor compound may further include a group II element.

Examples of group III-V semiconductor compounds further containing group II elements may include InZnP, InGaZnP, InAlZnP, and the like.

Examples of group III-VI semiconductor compounds may include binary compounds such as GaS, Ga2S3, GaSe, Ga2Se3, GaTe, InS, InSe, In2Se3, InTe, etc.; ternary compounds such as InGaS3, InGaSe3, etc.; or a combination thereof.

Examples of group I-III-VI semiconductor compounds may include ternary compounds such as AgInS, AgInS2, AgInSe2, AgGaS, AgGaS2, AgGaSe2, CuInS, CuInS2, CuInSe2, CuGaS2, CuGaSe2, CuGaO2, AgGaO2, AgAlO2, etc.; quaternary compounds such as AgInGaS2, AgInGaSe2, etc.; or a combination thereof.

Examples of group IV-VI semiconductor compounds may include binary compounds such as SnS, SnSe, SnTe, PbS, PbSe, PbTe, etc.; ternary compounds such as SnSeS, SnSeTe, SnSTe, PbSeS, PbSeTe, PbSTe, SnPbS, SnPbSe, SnPbTe, etc.; quaternary compounds such as SnPbSSe, SnPbSeTe, SnPbSTe, etc.; or a combination thereof.

Group IV elements or compounds may include single element compounds such as Si, Ge, etc.; binary compounds such as SiC, SiGe, etc.; or a combination thereof.

Each element included in a multi-element compound, such as a binary compound, a ternary compound, and a quaternary compound, may exist in a particle at a uniform concentration or a non-uniform concentration.

In other words, the chemical formula refers to the type of elements included in the compound, and the element ratio in the compound may be different.

For example, AgInₓGa₁₋ₓS₂ (x is a real number between 0 and 1) may mean AgInGaS2.

Quantum dots may have a single structure or a core-shell structure in which the concentration of each element contained in the quantum dot is uniform.

For example, the material contained in the core and the material contained in the shell may be different from each other.

The shell of the quantum dot may serve as a protective layer to maintain semiconductor properties by preventing chemical denaturation of the core and/or as a charging layer to impart electrophoretic properties to the quantum dot.

The shell may have single or multilayer.

The interface between the core and the shell may have a concentration gradient in which the concentration of elements present in the shell decreases toward the center.

The shell of quantum dots may include a metal oxide, a non-metal oxide, a semiconductor compound, or a combination thereof.

Examples of oxides of metals or non-metals may include binary compounds such as SiO2, Al2O3, TiO2, ZnO, MnO, Mn2O3, Mn3O4, CuO, FeO, Fe2O3, Fe3O4, CoO, Co3O4, NiO, etc.; ternary compounds such as MgAl2O4, CoFe2O4, NiFe2O4, CoMn2O4, etc.; or a combination thereof.

Examples of semiconductor compounds may include group III-VI semiconductor compounds, as described herein; Group II-VI semiconductor compounds; Group III-V semiconductor compounds; Group III-VI semiconductor compounds; Group I-III-VI semiconductor compounds; Group IV-VI semiconductor compounds; or a combination thereof.

For example, semiconductor compounds may include CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or a combination thereof.

Each element included in a multi-element compound, such as a binary compound or a ternary compound, may exist in a particle at a uniform or non-uniform concentration.

In other words, the chemical formula refers to the type of elements included in the compound, and the element ratio in the compound may be different.

Quantum dots may have a full width of half maximum FWHM of the light emitting wavelength spectrum of less than or equal to about 45 nm. For example, quantum dots may have a full width of half maximum FWHM of the light emitting wavelength spectrum of less than or equal to about 40 nm. For example, quantum dots may have a full width of half maximum FWHM of the light emitting wavelength spectrum of less than or equal to about 30 nm. Color purity or color reproducibility may be improved in this range.

Since the light emitted through these quantum dots is emitted in all directions, the optical viewing angle may be improved.

The shape of the quantum dots may be spherical, pyramid-shaped, multi-arm, or cubic nanoparticles, nanotubes, nanowires, nanofibers, nanoplate-shaped particles, etc.

By adjusting the size of the quantum dot or the element ratio in the quantum dot compound, the energy band gap may be adjusted, so light of various wavelengths may be obtained from the quantum dot emitting layer.

Therefore, by using quantum dots as described above (using quantum dots of different sizes or having different element ratios in the quantum dot compound), a light emitting element that emits light of various wavelengths may be implemented.

For example, the size of the quantum dots or the element ratio in the quantum dot compound may be selected to emit red, green, and/or blue light.

Quantum dots may be configured to emit white light by combining light of various colors.

The color conversion layer QDr, QDg may further include a scattering member such as a transmission layer in addition to the semiconductor nanocrystals.

The color conversion layer QDr, QDg may also be refracted and dispersed by the scattering member.

The scattering member according to one embodiment may be formed of TiO₂.

The first transparent layers TLb, TLs1 may include a first transparent layer for pixels TLb located between the wall BM and not overlapping the light emitting element LDb in a plan view, and a first transparent layer for sensing TLs1 overlapping the light receiving element PD in a plan view.

The first transparent layer for pixels TLb may allow the wavelength of light emitted from the light emitting element LDb to pass through without changing, and the first transparent layer for sensing TLs1 may allow light transmitted from the outside to be delivered to the light receiving element PD without being blocked.

The first transparent layer TLb, TLs1 may be formed of a transparent organic material, and various transparent organic materials may be used such as polyimide, polyamide, an acrylic resin, benzocyclobutene, and a phenolic resin.

A low refractive index layer LR may be located on the wall BM, the color conversion layer QDr, QDg, and the first transparent layer TLb, TLs1.

The low refractive index layer LR may include low refractive index structures.

For example, the low refractive index layer LR may include multiple low refractive index structures, for example, a first low refractive index structure and a second low refractive index structure.

According to embodiments, the low refractive index structures may include a silica-based material, for example, hollow silica.

Low refractive structures may have a spherical shape.

The low refractive index layer LR may selectively reflect blue light that fails to turn red in the red color conversion layer QDr, back to the red color conversion layer QDr.

The low refractive index layer LR may selectively reflect blue light that fails to turn green in the green color conversion layer QDg back to the green color conversion layer QDg.

The first low refractive index structure and the second low refractive structure included in the low refractive index layer LR may have different sizes and/or refractive indices.

According to an embodiment, low refractive index structures having three or more sizes and/or refractive indices may be disposed in the low refractive index layer LR.

According to embodiments, the low refractive structures may be disposed on the wall BM, the color conversion layer QDr, QDg, and the first transparent layer TLb, TLs1 in a dissolved state in a solvent.

In an embodiment, the solvent may have a higher refractive index than the low refractive index structure, so if the solvent remains, the refractive index of the low refractive index layer may increase.

To prevent this problem, the solvent may contain highly volatile alcohols.

For example, the solvent may include isopropyl alcohol.

Therefore, if the low refractive structures are disposed on the wall BM, the color conversion layer QDr, QDg, and the first transparent layer TLb, TLs1 while dissolved in a solvent, the solvent can be readily evaporated.

Alcohol solvents may have a low boiling point and may be evaporated at low temperatures.

Therefore, the alcohol solvent may be evaporated by applying heat in a range that does not damage other layers of the display device.

Accordingly, the refractive index of the low refractive index layer LR containing only low refractive structures may be effectively lowered.

The color filters CFr, CFg, CFb and the second transparent layer TLs2 may be disposed above the low refractive index layer LR, and the color filters CFr, CFg, CFb and the second transparent layer TLs2 may be covered by the planarization layer OC.

The color filters CFr, CFg, CFb may transmit only light of the corresponding wavelength and block light of the other wavelengths, thereby blocking blue light that has not been converted in the color conversion layer QDr, QDg.

As a result, the light that passes through the color filters CFr, CFg, CFb may correspond to each of the three primary colors of light.

The second transparent layer TLs2 may be formed of a transparent organic material, so that light transmitted from the outside is not blocked and is transmitted to the first transparent layer for sensing TLs1 and the light receiving element PD.

The planarization layer OC may be disposed on the color filters CFr, CFg, CFb and the second transparent layer TLs2 to flatten the top of the color filters CFr, CFg, CFb.

The planarization layer OC may be a colorless light-transmitting layer that does not have a color in the visible light band.

The second transparent layer TLs2 and the planarization layer OC may be formed of a transparent organic material, and may include an organic material such as polyimide, polyamide, an acrylic resin, benzocyclobutene, and a phenol resin.

According to an embodiment, since the planarization layer OC is transparent, the second transparent layer TLs2 may be omitted.

Referring to FIG. 4, the light emitting element of the red or green pixel may be the first light emitting element and the light emitting element of the blue pixel may be the second light emitting element.

The display panel DP may include a first pixel circuit unit PCr, PCg, a second pixel circuit unit PCb, and a light sensing circuit unit PDC located on a substrate, first light emitting elements LDr, LDg electrically connected to the first pixel circuit unit PCr, PCg, a second light emitting element LDb electrically connected to the second pixel circuit unit PCb, a light receiving element PD electrically connected to a light sensing circuit unit PDC, a first color conversion layer QDr, QDg located in front of the first light emitting element LDr, LDg, a first transparent layer for pixels TLb located in front of the second light emitting element LDb, a first transparent layer for sensing TLs1 located in front of the light receiving element PD, first color filters CFr, CFg located in front of the first color conversion layer QDr, QDg, and a second color filter CFb located on the front side of the first transparent layer for pixels TLb.

The first color conversion layer may be a color conversion layer that converts blue light into red light or green light, the first color filter may be a red or green color filter, and the second color filter may be a blue color filter.

The pixel defining layer PDL may partition the first light emitting elements LDr, LDg, the second light emitting elements LDb, and the light receiving element PD, and the wall BM may divide the first color conversion layer QDr, QDg, a first transparent layer for pixels TLb, and a first transparent layer for sensing TLs1.

The first light emitting element LDr, LDg may include a first electrode (see Anoder, Anodeg in FIG. 6), a first light emitting layer (see EMLb in FIG. 6), and a second electrode (see Cathode in FIG. 6), the second light emitting element LDb may include a first electrode (see Anodeb in FIG. 6), a second light emitting layer (see EMLb in FIG. 6), and a second electrode (see Cathode in FIG. 6), a light receiving element PD may include a first electrode (see Anodepd in FIG. 6), a sensing layer (see OPDL in FIG. 6), and a second electrode (see Cathode in FIG. 6), and the first light emitting layer and the second light emitting layer may emit blue light.

The first electrodes (see Anoder and Anodeg in FIG. 6) of the first light emitting elements LDr, LDg, the first electrodes (see Anodeb in FIG. 6) of the second light emitting elements LDb and the first electrode (see Anodepd in FIG. 6) of the light receiving element PD may be located in a same layer.

The second electrode (see Cathode in FIG. 6) of the first light emitting elements LDr, LDg, the second electrode (Cathode) of the second light emitting element LDb, and the second electrode of the light receiving element PD may be located in a same layer and be electrically connected.

The first light emitting layer (see EMLb in FIG. 6), the second light emitting layer (see EMLb in FIG. 6), and the sensing layer (see OPDL in FIG. 6) may be located on a same layer.

In case that the first light emitting element further includes a functional layer located between the first light emitting layer and the first electrode or between the first light emitting layer and the second electrode, and the light receiving element includes a functional layer, the functional layer of the light receiving element may be formed continuously with the functional layer of the first light emitting element, and may be formed continuously beyond the pixel defining layer PDL.

The low refractive index layer LR may have a structure covering the wall BM, the first color conversion layer QDr, QDg, the first transparent layer for pixels TLb, and the first transparent layer for sensing TLs1.

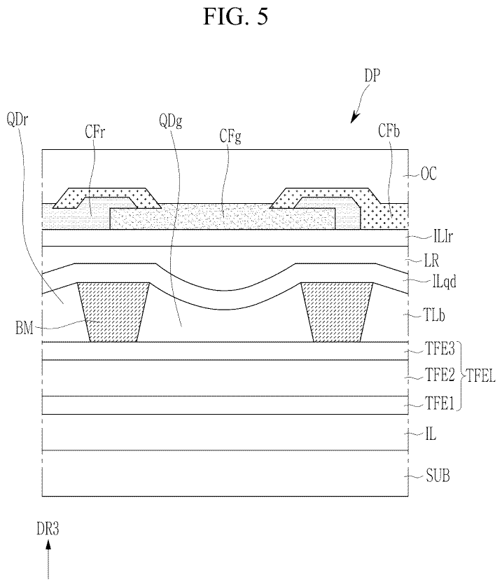

Referring to FIG. 5, an insulating layer may be further included above and below the low refractive index layer LR.

For example, the lower insulating layer ILqd for the low refractive index layer LR may be disposed between the wall BM, the first color conversion layer QDr, QDg, the first transparent layer for the pixel TLb, the first transparent layer for the sensing TLs1, and the low refractive index layer LR, and the upper insulating layer ILlr for the low refractive index layer LR may be located between the low refractive index layer LR and the first color filters CFr, CFg and the second color filter CFb.

The overlapping portion where the first color filters CFr, CFg and the second color filter CFb overlap may overlap the wall BM in a plan view.

In the above, the schematic stacked structure of the display panel DP was described through FIG. 4.

Hereinafter, the upper structure of the encapsulation layer TFEL of the display panel DP will be described in more detail through FIG. 5.

FIG. 5 is a schematic cross-sectional view of the display area of a display panel according to another embodiment.

Although FIG. 5 shows the upper structure of the green pixel as the upper part of the encapsulation layer TFEL, pixels of other colors or the upper part of the sensing unit may also have a similar structure.

In FIG. 5, the structure between the encapsulation layer TFEL and the insulating layer IL is omitted.

The encapsulation layer TFEL according to the embodiment of FIG. 5 may include a first encapsulation layer TFE1, a second encapsulation layer TFE2, and a third encapsulation layer TFE3.

The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

The first encapsulation layer TFE1 and the third encapsulation layer TFE3 may each include one or more inorganic insulating materials.

The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material.

Polymer-based materials may include an acrylic resin, an epoxy resin, polyimide, and polyethylene.

For example, the second encapsulation layer TFE2 may include an acrylic resin including polymethyl methacrylate or polyacrylic acid.

The second encapsulation layer TFE2 may be formed by curing a monomer or applying a polymer.

The encapsulation layer TFEL with this structure may be repeatedly formed of an inorganic layer and an organic layer to prevent moisture or air from entering the light emitting layer of the light emitting element.

A wall BM, a color conversion layer QDr, QDg, and a first transparent layer for pixels TLb may be located on the encapsulation layer TFEL.

Referring to FIG. 5, the wall BM may have a column structure with reverse tapered sides.

However, the cross-sectional structure of the wall BM may be formed in various structures, such as a tapered structure or a pillar structure with side surfaces close to vertical as shown in FIG. 4.

The wall BM may contain an inorganic black pigment or an organic black pigment to block or absorb light in order to prevent light emitted from the light emitting elements LDr, LDg, LDb from invading and mixing colors.

The inorganic black pigment may be carbon black, and the organic black pigment may include at least one of lactam black, perylene black, and aniline black.

The wall BM may be formed of the previously described black organic material for the pixel defining layer PDL.

A color conversion layer QDr, QDg and a first transparent layer for pixels TLb may be located between the wall BM, and the color conversion layer QDr, QDg and the first transparent layer for pixels TLb may be formed between the wall BM by an inkjet method.

A first transparent layer for sensing TLs1 may be positioned on the sensing unit, as shown in FIG. 4.

A lower insulating layer ILqd for the low refractive index layer LR, a low refractive index layer LR, and an upper insulating layer ILlr for the low refractive index layer LR may be sequentially stacked above the wall BM, the color conversion layer QDr, QDg, and the first transparent layer for pixels TLb.

The lower insulating layer ILqd for the low refractive index layer LR and the upper insulating layer ILlr for the low refractive index layer LR may be formed of an inorganic insulating layer such as aluminum oxide, titanium oxide, tantalum oxide, hafnium oxide, zinc oxide, silicon oxide, silicon nitride, and/or silicon oxynitride.

Referring to FIG. 5, the lower insulating layer ILqd for the low refractive index layer LR may have a structure with a step difference due to a height difference between the wall BM, the color conversion layer QDr, QDg, and the first transparent layer for pixels TLb.

The low refractive index layer LR may include low refractive index structures.

For example, the low refractive index layer LR may include multiple low refractive index structures, for example, a first low refractive index structure and a second low refractive index structure.

According to embodiments, the low refractive index structures may include a silica-based material, for example, hollow silica.

Low refractive structures may have a spherical shape.

The low refractive index layer LR may selectively reflect blue light that fails to turn red in the red color conversion layer QDr, back to the red color conversion layer QDr.

The low refractive index layer LR can selectively reflect blue light that fails to turn green in the green color conversion layer QDg, back to the green color conversion layer QDg.

The first low refractive index structure and the second low refractive structure included in the low refractive index layer LR may have different sizes and/or refractive indices.

According to an embodiment, low refractive index structures having three or more sizes and/or refractive indices may be disposed in the low refractive index layer LR.

According to embodiments, the low refractive structures may be disposed on the wall BM, the color conversion layer QDr, QDg, and the first transparent layer TLb, TLs1 in a dissolved state in a solvent.

Typically, the solvent may have a higher refractive index than the low refractive index structure, so if the solvent remains, the refractive index of the low refractive index layer may increase.

To prevent this problem, the solvent may contain highly volatile alcohols.

For example, the solvent may include isopropyl alcohol.

Therefore, if the low refractive structures are disposed on the wall BM, the color conversion layer QDr, QDg, and the first transparent layer TLb, TLs1 while dissolved in a solvent, the solvent may be readily evaporated.

Alcohol solvents may have a low boiling point and may be evaporated at low temperatures.

Therefore, the alcohol solvent may be evaporated by applying heat in a range that does not damage other layers of the display device.

Accordingly, the refractive index of the low refractive index layer LR containing only low refractive structures may be effectively lowered.

The color filters CFr, CFg, CFb may be positioned on the upper insulating layer ILlr for the low refractive index layer LR, and on the other hand, a second transparent layer TLs2 may be positioned on the sensing unit, as shown in FIG. 4.

The three color filters CFr, CFg, CFb may overlap each other in the overlapping portion of the wall BM in a plan view.

According to an embodiment, only two color filters (e.g., red and blue color filters CFr, CFb) among the color filters CFr, CFg, CFb may overlap in a plan view.

Color mixing may be prevented by overlapping multiple color filters to serve as a light blocking member.

This prevention of color mixing may also occur in the wall BM, and may also occur in the pixel defining layer PDL if the pixel defining layer PDL includes a black organic material.

Therefore, in this embodiment, it may be possible to prevent color mixing even if a light blocking member that separates the color filter is not included.

Only one color filter of the corresponding color may be located at the opening of the wall BM, for example, at a position that overlaps the color conversion layer QDr, QDg or the first transparent layer TLb in a plan view.

Referring to FIG. 5, the green color filter CFg may be located in a portion that overlaps the green color conversion layer QDg in a plan view.

A second transparent layer TLs2 may be positioned on the sensing unit, as shown in FIG. 4.

The color filters CFr, CFg, CFb may be covered with a planarization layer OC.

In the above, the upper structure of the encapsulation layer TFEL was described in detail through FIG. 5.

Hereinafter, the stacked structure of the light emitting element and the light receiving element of the lower structure of the encapsulation layer TFEL will be described in detail through FIG. 6.

FIG. 6 is a schematic cross-sectional view of a light emitting element and a light receiving element in a light emitting display device according to an embodiment.

The light emitting elements LDr, LDg, LDb may each include a first electrode Anoder, Anodeg, Anodeb, a light emitting layer EMLb, and a second electrode Cathode, and may further include a functional layer located on sides of the light emitting layer EMLb and including a hole injection layer HIL, a hole transport layer HTL, an electron transport layer ETL, and an electron injection layer EIL.

The three light emitting elements LDr, LDg, LDb may emit a same blue light, and as a result, in FIG. 6, the three light emitting elements LDr, LDg, LDb may include a same light emitting layer EMLb.

A hole injection layer HIL and a hole transport layer HTL may be positioned below the emitting layer EMLb, and an electron transport layer ETL and an electron injection layer EIL may be positioned above the emitting layer EMLb.

In FIG. 6, a pixel defining layer (see PDL in FIG. 4) may be located between adjacent light emitting elements LDr, LDg, LDb, the first electrodes Anoder, Anodeg, Anodeb may be located below the pixel defining layer, and a second electrode Cathode may be located on the pixel defining layer.

The first electrodes Anoder, Anodeg, Anodeb included in the light emitting element LDr, LDg, LDb may be electrically separated from each other, and the second electrode Cathode included in the light emitting element LDr, LDg, LDb may be electrically connected.

In FIG. 6, the light emitting layer EMLb and the functional layer included in the light emitting elements LDr, LDg, LDb are shown as being separated from each other, but the disclosure is not limited thereto, and according to another embodiment, the light emitting layer EMLb and the functional layer included in the light emitting elements LDr, LDg, LDb may be connected to each other through a structure that extends over the upper surface of the pixel defining layer.

According to an embodiment, the light emitting layers EMLb may not be connected to each other, but may have a structure in which only the functional layers are connected.

The functional layer described in FIG. 6 may include a hole injection layer HIL, a hole transport layer HTL, an electron transport layer ETL, and an electron injection layer EIL, but the disclosure is not limited thereto, and according to another embodiment, at least one of these four layers may be omitted.

The light receiving element PD may include a first electrode Anodepd, a sensing layer OPDL, and a second electrode Cathode, and additionally, functional layers included in the light emitting elements LDr, LDg, LDb may be located on either side of the sensing layer.

For example, the light receiving element PD may also include a hole injection layer HIL, a hole transport layer HTL, an electron transport layer ETL, and an electron injection layer EIL as functional layers, a hole injection layer and a hole transport layer HTL may be located below the sensing layer OPDL, and an electron transport layer ETL and an electron injection layer EIL may be located above the sensing layer OPDL.

According to an embodiment, at least one layer among these four layers may be omitted.

The second electrode Cathode and the functional layer included in the light receiving element PD may have a structure connected to the second electrode Cathode and the functional layer included in the light emitting elements LDr, LDg, LDb.

The first electrode Anodepd and the sensing layer OPDL included in the light receiving element PD may have a separate structure from the first electrode Anoder, Anodeg, Anodeb and the light emitting layer EMLb included in the light emitting elements LDr, LDg, LDb.

According to an embodiment, at least some of the functional layers included in the light receiving element PD may have a structure that is separated from the functional layers included in the light emitting elements LDr, LDg, LDb.

An embodiment in which only one light emitting layer EMLb is included in the light emitting elements LDr, LDg, LDb in FIG. 6 is shown.

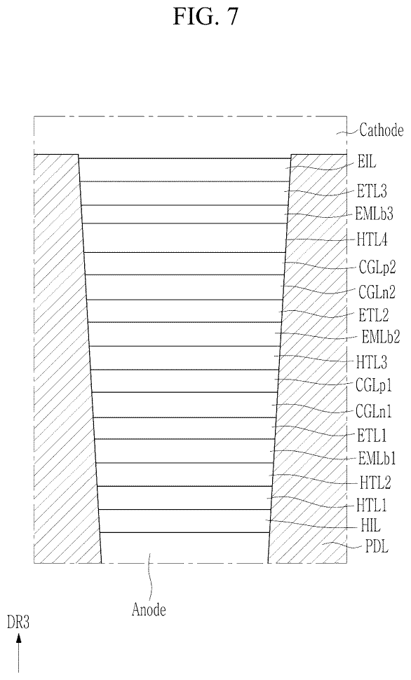

However, the disclosure is not limited thereto, and according to another embodiment, the light emitting element LDr, LDg, LDb may include two or more light emitting layers, and an embodiment will be described in FIG. 7.

FIG. 7 is a schematic cross-sectional view of a light emitting element in a light emitting display device according to another embodiment.

In FIG. 7, a pixel defining layer PDL, a first electrode Anode, and a second electrode Cathode included in the light emitting element are shown, and between the sub-light emitting layers EMLb1, EMLb2, EMLb3 included in the light emitting element and the functional layer are enlarged.

In the embodiment of FIG. 7, the light emitting element may include three sub-light emitting layers EMLb1, EMLb2, EMLb3, and between the first electrode Anode and the first sub-light emitting layer EMLb1, a hole injection layer HIL and a first hole transport layer HTL1 and a second hole transport layer HTL2 may be located, and a first electron transport layer ETL1 and a first n charge generation layer may be located between the first sub-light emitting layer EMLb1 and the second sub-light emitting layer EMLb2. CGLn1, a first p charge generation layer CGLp1, and a third hole transport layer HTL3 may be located, and a second electron transport layer ETL2 may be located between the second sub-light emitting layer EMLb2 and the third emitting layer EMLb3, the second n charge generation layer CGLn2, the second p charge generation layer CGLp2, and the fourth hole transport layer HTL4 may be located between the third light emitting layer EMLb3 and the second electrode Cathode, a third electron transport layer ETL3 and an electron injection layer EIL may be located therein.

In FIG. 7, the structure in which the three sub-light emitting layers EMLb1, EMLb2, EMLb3 and the functional layer are separated by the pixel defining layer PDL is shown, but the disclosure is not limited thereto, and according to another embodiment, the side and top surfaces of the pixel defining layer PDL may be separated from each other by the pixel defining layer PDL, which may have a structure connected to three adjacent sub-light emitting layers EMLb1, EMLb2, EMLb3 and a functional layer.

At least some of the functional layers in FIG. 7 may have a structure connected to the functional layer of the adjacent light receiving element PD, but the sub-light emitting layers EMLb1, EMLb2, EMLb3 may not be connected to the light receiving element PD, and the light receiving element PD may have a sensing layer OPDL at the location of the sub-light emitting layers EMLb1, EMLb2, EMLb3.

The sensing layer OPDL of the light receiving element PD may include only one or two sensing layers, and some of the functional layers included in the light emitting element may not be connected to the light receiving element.

According to the structure of FIG. 7, the light emitting element may further include one or more additional light emitting layers.

A charge generation layer may be further included as a functional layer between the light emitting layer and the additional light emitting layer, and the charge generation layer may be located between the hole transport layer and the electron transport layer.

A circuit structure of a sensing unit located in the display area according to an embodiment will be described through FIG. 8 and FIG. 9.

First, the circuit structure of the sensing unit will be described through FIG. 8.

FIG. 8 is a schematic diagram of an equivalent circuit of one sensing unit included in a light emitting display device according to an embodiment.

The sensing unit may include a light receiving element (PD; hereinafter also referred to as a photo diode) and a light sensing circuit unit (PDC; hereinafter also referred to as a second circuit unit).

The light receiving element PD may be an organic photo diode, and the remaining portion of the sensing unit excluding the light receiving element may constitute a light sensing circuit unit PDC.

In the embodiment of FIG. 8, the light sensing circuit unit PDC of the sensing unit may include three sensing transistors Ts1, Ts2, Ts3 and one capacitor (Cs; also referred to as a sensing capacitor), and may not include the sensing capacitor Cs.

The sensing unit may be connected to the first sensing scan line 161s to which the sensing scan signal SCAN is applied, the second sensing scan line 162s to which the sensing reset signal GRE is applied, and the sensing line 171s that read out current or voltage READ OUT.

The sensing unit may include a first power voltage line 172s to which a first power voltage (V1; hereinafter referred to as common voltage) is applied, a reset voltage line 173s to which a reset voltage Vreset is applied, and a second driving voltage line to which a driving low voltage (ELVSS; hereinafter also referred to as first power voltage line 172s) is applied.

The circuit structure of the sensing unit, focusing on each element (transistor, capacitor, light receiving element) included in the sensing unit, is as follows.

The first sensing transistor (Ts1; hereinafter also referred to as an amplifying transistor) may include a gate electrode connected to the anode of the light receiving element PD, the second electrode of the sensing capacitor Cs, and the second electrode of the third sensing transistor Ts3, a first electrode (input side electrode) connected to the first power voltage line 172s to which the first power voltage V1 is applied, and a second electrode (output side) connected to the first electrode of the second sensing transistor Ts2.

The first power voltage V1 may be applied to the first electrode of the first sensing transistor Ts1 of all sensing units located in the display area.

The first sensing transistor Ts1 may serve to transfer the amplified output according to the anode voltage of the light receiving element PD to the second sensing transistor Ts2.

The second sensing transistor (Ts2; hereinafter also referred to as output transistor) may include a gate electrode connected to the first sensing scan line 161s to which the sensing scan signal SCAN is applied, a first electrode (input electrode) connected to the second electrode of the first sensing transistor Ts1, and a second electrode (output electrode) connected to the sensing line 171s.

The second sensing transistor Ts2 may serve to detect the amplified output of the first sensing transistor Ts1 by outputting it to the sensing line 171s.

The third sensing transistor (Ts3; hereinafter also referred to as reset transistor) may include a gate electrode connected to the second sensing scan line 162s to which the sensing reset signal GRE is applied, a first electrode (input electrode) connected to a reset voltage line 173s to which the reset voltage Vreset is applied, and a second electrode (output electrode) connected to the gate electrode of the first sensing transistor Ts1, the anode of the light receiving element PD, and the second electrode of the sensing capacitor Cs.

The third sensing transistor Ts3 may serve to reset the anode voltage of the light receiving element PD to the reset voltage Vreset.

In this embodiment, the three sensing transistors Ts1, Ts2, Ts3 may be formed of n-type transistors, and each transistor may be turned on in case that the voltage of the gate electrode is at a high level and turned off in case that the voltage is at a low level.

The semiconductor layer included in each transistor may include a polycrystalline silicon semiconductor or an oxide semiconductor, or an amorphous semiconductor or a single crystal semiconductor may be used.

The sensing capacitor Cs may include the first electrode connected to the second driving voltage line 179, and a second electrode connected to the gate electrode of the first sensing transistor Ts1, the anode of the light receiving element PD, and the second electrode of the third sensing transistor Ts3.

The sensing capacitor Cs may serve to keep the voltage of the gate electrode of the first sensing transistor Ts1 and the voltage of the anode of the light receiving element PD constant.

According to another embodiment, the first electrode of the sensing capacitor Cs may be connected to a voltage line other than the second driving voltage line 179, or the sensing capacitor Cs may be omitted.

The light receiving element PD may include an anode connected to the gate electrode of the first sensing transistor Ts1, the second electrode of the third sensing transistor Ts3, and the second electrode of the sensing capacitor Cs, and a cathode connected to the second driving voltage line 179.

The light receiving element PD may change the voltage value of the gate electrode of the first sensing transistor Ts1 and the second electrode of the sensing capacitor Cs by generating or reducing photo charges based on the intensity of external light.

The light sensing circuit unit PDC shown in FIG. 8 is only an embodiment, and the configuration of the light sensing circuit unit PDC may be modified.

Below, the operation of the sensing unit based on the signal of FIG. 9 applied to the sensing unit of FIG. 8 will be described.

FIG. 9 is a waveform diagram showing the signal applied to the sensing unit of FIG. 8.

In FIG. 9, the first light emitting signal EM1 may be a signal applied to the pixel, and a light emitting period and a non-light emitting period may be divided based on the first light emitting signal EM1.

The light emitting period may be a section in which the pixel of the display unit emits light, and the non-light emitting period may be a section in which the pixel is prepared before emitting light, and may include an initialization section, a compensation section, and a writing section.

Referring to FIG. 9, during the non-light emitting period, the sensing scan signal SCAN and the sensing reset signal GRE may be sequentially applied to the sensing unit, and during the light emitting period the display unit may emit light, the light receiving element PD of the sensing unit may be exposed to external objects, and a light exposure period may occur where the user is exposed to light reflected from an external object (for example, a finger's fingerprint, which is one of the user authentication methods).

The light emitting period of the display unit and the light exposure period of the sensor may be sections with the same starting point and end point.

The operation of the sensing unit is described in the following order: light exposure period, sensing section, and reset section.

The light exposure period may be a section in which the light emitting element of the display unit emits light, and the light emitted from the display unit may be reflected by an external object (for example, a finger's fingerprint) and transmitted to the light receiving element PD of the sensing unit.

In case that the external reflected light is transmitted to the light receiving element PD, the light receiving element PD may generate or reduce photo charges based on the intensity of the external light and generate or reduce light charges to the gate electrode of the first sensing transistor Ts1, and the sensing capacitor Cs may change the voltage value of the second electrode from the existing voltage (reset voltage Vreset) value.

In case that the light exposure period ends, the light receiving element PD may no longer generate or decrease light charges, so the voltage value of the gate electrode of the first sensing transistor Ts1 and the second electrode of the sensing capacitor Cs may no longer change and may be maintained.

Afterwards, the sensing scan signal SCAN may change to high voltage and enter the sensing section.

The second sensing transistor Ts2 may be turned on by the sensing scan signal SCAN, and the amplified output of the first sensing transistor Ts1 may be output to the sensing line 171s.

The amplified output of the first sensing transistor Ts1 may be determined according to the voltage of the gate electrode of the first sensing transistor Ts1, for example, the anode voltage of the light receiving element PD.

The anode voltage of the light receiving element PD may change depending on the magnitude of light transmitted to the light receiving element PD during the light exposure period.

Therefore, the output value from the second sensing transistor Ts2 may have a value corresponding to the magnitude of light transmitted to the light receiving element PD during the light exposure period.

Afterwards, the sensing scan signal SCAN may change to a low voltage, and the sensing reset signal GRE may change to a high voltage to enter the reset section.

By the sensing reset signal GRE, the third sensing transistor Ts3 may be turned on, and the gate electrode of the first sensing transistor Ts1, the anode of the light receiving element PD, and the second electrode of the sensing capacitor Cs may be reset to the reset voltage Vreset.

Afterwards, in case that the light exposure period is entered again, external light may be transmitted to the light receiving element PD, and the voltage of the anode of the light receiving element PD, which is reset to the reset voltage Vreset, may be changed.

In the above description, the signals applied to the display unit and the sensing unit located in the display area are described as being independent from each other, but the disclosure is not limited thereto, and in another embodiment, some signals may be applied at the same time.

For example, the sensing scan signal SCAN or the sensing reset signal GRE applied to the sensing unit may be applied at the same time as one of the first scan signal GW, the second scan signal GC, the third scan signal GR, and the fourth scan signal applied to the display unit.

As described above, if the display area includes both a display unit and a sensing unit, there may be an advantage in that the non-display area located outside the display area may be reduced and the display area can be expanded.

Various embodiments can be applied to the circuit structure of the pixels of the display unit, and not only various pixel circuits currently used in display devices but also various pixel circuits to be developed in the future may be applied.

For example, a pixel may include a driving transistor that generates and transmits a light emitting current to a light emitting element, and additionally include at least one switching transistor.

The switching transistor may include a transistor that is connected to the data line and transmits the data voltage to the gate electrode of the driving transistor, and other transistors that compensate the driving transistor or determine the timing operation of the driving transistor or convert the light emitting current of the driving transistor into a light emitting element may switch to allow power to be applied, and/or a transistor that initializes a node in the pixel.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light emitting display device, comprising:
a first pixel circuit unit, a second pixel circuit unit, and a light sensing circuit unit located on a substrate;
a first light emitting element electrically connected to the first pixel circuit unit;
a second light emitting element electrically connected to the second pixel circuit unit;
a light receiving element electrically connected to the light sensing circuit unit;
a first color conversion layer located on the first light emitting element;
a first transparent layer for pixels located on the second light emitting element;
a first transparent layer for sensing located on the light receiving element;
a first color filter located on the first color conversion layer; and
a second color filter located on the first transparent layer for pixels, wherein
the first light emitting element includes a first electrode, a first light emitting layer, and a second electrode,
the second light emitting element includes a first electrode, a second light emitting layer, and a second electrode,
the light receiving element includes a first electrode, a sensing layer, and a second electrode,
the first electrode of the first light emitting element, the first electrode of the second light emitting element, and the first electrode of the light receiving element are located on a same layer,
the second electrode of the first light emitting element, the second electrode of the second light emitting element, and the second electrode of the light receiving element are located on a same layer and are electrically connected, and
the first light emitting layer, the second light emitting layer, and the sensing layer are located on a same layer.

2. The light emitting display device of claim 1, wherein the first light emitting layer and the second light emitting layer emit blue light.

3. The light emitting display device of claim 2, wherein
the first color filter is a red color filter or a green color filter, and
the second color filter is a blue color filter.

4. The light emitting display device of claim 1, further comprising:
a second transparent layer located on the first transparent layer for sensing.

5. The light emitting display device of claim 1, wherein
the first light emitting element further includes a functional layer located between the first light emitting layer and the first electrode or between the first light emitting layer and the second electrode,
the light receiving element further includes a functional layer, and
the functional layer of the light receiving element and the functional layer of the first light emitting element are formed continuously.

6. The light emitting display device of claim 5, wherein the functional layer of the first light emitting element and the functional layer of the light receiving element are at least one of a hole injection layer, a hole transport layer, an electron injection layer, and an electron transport layer.

7. The light emitting display device of claim 6, wherein:
the hole injection layer and the hole transport layer are located between the first light emitting layer and the first electrode, and
the electron injection layer and the electron transport layer are positioned between the first light emitting layer and the second electrode.

8. The light emitting display device of claim 6, further comprising:
an additional light emitting layer; and
a charge generation layer between the first light emitting layer and the additional light emitting layer.

9. The light emitting display device of claim 8, wherein the charge generation layer is positioned between the hole transport layer and the electron transport layer.

10. The light emitting display device of claim 1, further comprising:
a pixel defining layer partitioning the first light emitting element, the second light emitting element, and the light receiving element; and
a wall partitioning the first color conversion layer, the first transparent layer for pixels, and the first transparent layer for sensing.

11. The light emitting display device of claim 10, wherein the wall has an inverse tapered side surface.

12. The light emitting display device of claim 10, wherein the wall includes a light absorbing material.

13. The light emitting display device of claim 10, further comprising:
a low refractive index layer covering the wall, the first color conversion layer, the first transparent layer for pixels, and the first transparent layer for sensing.

14. The light emitting display device of claim 13, further comprising:
a lower insulating layer for the low refractive index layer positioned between the low refractive index layer and the wall, the first color conversion layer, the first transparent layer for pixels, and the first transparent layer for sensing; and
an upper insulating layer for the low refractive index layer positioned between the low refractive index layer and the first color filter and the second color filter.

15. The light emitting display device of claim 14, wherein the lower insulating layer for the low refractive index layer has a step.

16. The light emitting display device of claim 10, wherein an overlapping portion where the first color filter and the second color filter overlap in a plan view overlaps the wall in a plan view.

17. A light emitting display device, comprising:
a first pixel circuit unit and a light sensing circuit unit located on a substrate;
a first light emitting element electrically connected to the first pixel circuit unit;
a light receiving element electrically connected to the light sensing circuit unit;
a first color conversion layer located on the first light emitting element;
a first transparent layer for sensing located on the light receiving element;
a first color filter located on the first color conversion layer; and
a second transparent layer located on the first transparent layer for sensing, wherein
the first light emitting element includes a first electrode, a first light emitting layer, a second electrode, and a functional layer located between the first light emitting layer and the first electrode or between the first light emitting layer and the second electrode,
the light receiving element includes a first electrode, a sensing layer, a second electrode, and a functional layer, and
the functional layer of the light receiving element and the functional layer of the first light emitting element are formed continuously.

18. The light emitting display device of claim 17, further comprising:
a pixel defining layer dividing the first light emitting element and the light receiving element; and
a wall dividing the first color conversion layer and the first transparent layer for sensing.

19. The light emitting display device of claim 18, further comprising:
a second pixel circuit unit located on the substrate;
a second light emitting element electrically connected to the second pixel circuit unit;
a first transparent layer for pixels located on the second light emitting element; and
a second color filter located on the first transparent layer for pixels, wherein
the second light emitting element includes a first electrode, a second light emitting layer, a second electrode, and a functional layer located between the second light emitting layer and the first electrode or between the second light emitting layer and the second electrode, and
the functional layer of the light receiving element and the functional layer of the second light emitting element are formed continuously.

20. The light emitting display device of claim 18, further comprising:
a low refractive index layer covering the wall, the first color conversion layer, the first transparent layer for pixels, and the first transparent layer for sensing.
